(19) United States
(12) Patent Application Publication
(10) Pub. No.: US 2005/0224919 A1
(43) Pub. Date: Oct. 13, 2005

(54) Spacer die structure and method for attaching

(75) Inventor: Seung Wook Park, Seoul (KR)

Correspondence Address: HAYNES BEFFEL & WOLFELD LLP, P O BOX 366, HALF MOON BAY, CA, 94019, US

(73) Assignee: ChipPAC, Inc, Fremont, CA (US)

(21) Appl. No.: 10/959,659

(22) Filed: Oct. 6, 2004

Related U.S. Application Data
(60) Provisional application No. 60/558,670, filed on Apr. 1, 2004.

(51) Int. Cl. H01L 23/544

(52) U.S. Cl. 257/620

(57) ABSTRACT

A semiconductor spacer structure comprises in order a backgrinding tape layer, a spacer adhesive layer, a semiconductor spacer layer, a dicing tape layer. A second spacer adhesive layer may be used between the semiconductor spacer layer and the dicing tape layer. In a method for attaching a semiconductor spacer die to a support surface, a first subassembly, comprising a spacer wafer having first and second sides, a backgrinding tape layer and a spacer adhesive layer between the first side and the backgrinding tape layer, is obtained. The second side of the spacer wafer is background to create a second subassembly, which is secured to a dicing tape with the backgrinding tape layer exposed. The backgrinding tape is removed from the spacer adhesive layer and the resulting structure is diced to create spacer/adhesive die structures comprising spacer die and adhesive. A spacer/adhesive die structure is secured to a support surface with the adhesive exposed. A second spacer adhesive layer may be adhered to the second side of the spacer wafer after backgrinding step for securing the resulting adhesive/spacer/adhesive die structure to the support surface.

### CROSS-REFERENCE TO RELATED APPLICATIONS

This application claims priority from U.S. Provisional Application No. 60/558,670, filed Apr. 1, 2004, titled “Spacer die structure and method for attaching”.

### BACKGROUND

The present invention relates to semiconductor spacer structures used in the fabrication of multi-chip modules, and to the manufacturing method of such packages.

To obtain the maximum function and efficiency from the minimum package, various types of increased density packages have been developed. Among these various types of packages is the so-called multi-chip module, multi-chip package or stacked chip package. A multi-chip module includes one or more integrated circuit semiconductor chips, often referred to as circuit die, stacked one onto another to provide the advantages of light weight, high density, and enhanced electrical performance. The multi-chip packages may contain all circuit die or a mixture of circuit die and spacer die, the spacer die typically being used to separate circuit die.

Semiconductor chip packaging process typically begins with wafer dicing, that is, sawing a semiconductor wafer to separate the wafer into individual semiconductor devices or chips. Before sawing, a wafer mounting tape is typically attached to the backside of the wafer. The wafer mounting tape keeps the chips together after the sawing.

The semiconductor chip is typically adhered to a previously mounted chip or to the substrate with a paste (typically an epoxy paste adhesive) or a film adhesive. Generally, paste adhesives have been used more often than film adhesives. However, some multi-chip modules are more successfully fabricated using film adhesives because the thickness of adhesive film is uniform so that there is minimal or no tilt of the semiconductor chips and no fillet of adhesive encircling the semiconductor chip. Moreover, no resin is bled so that it is suitable for multi chip stacking and packages with tight design tolerances or thinner chip.

In one method of fabricating a multi-chip module using film adhesive, an adhesive film is laminated directly to the backside of the semiconductor wafer and then the wafer is diced into individual semiconductor chips using conventional wafer dicing equipment. For stacking the semiconductor chips, each chip is lifted by a chip-bonding tool, which is usually mounted at the end of a pick-and-place device, and mounted onto the substrate or onto a semiconductor chip mounted previously. This method requires special film laminating equipment. However, it can shorten fabrication time and lower cost because the paste-dispensing process is not needed.

After the chip mounting process, bonding pads of the chips are connected to bonding pads of the substrate with Au or Al wires during a wire bonding process to create an array of semiconductor chip devices. Finally, the semiconductor chips and their associated wires connected to the substrate are encapsulated, typically using an epoxy-molding compound, to create an array of encapsulated semiconductor devices. The molding compound protects the semiconductor devices from the external environment, such as physical shock and humidity. After encapsulation, the encapsulated devices are separated, typically using a laser saw, into individual semiconductor chip packages.

### SUMMARY

A first aspect of the present invention is directed to a semiconductor spacer structure comprising a backgrinding tape layer, followed by a spacer adhesive layer, followed by a semiconductor spacer layer, followed by a dicing tape layer. The semiconductor spacer structure may also comprise a second spacer adhesive layer between the semiconductor spacer layer and the dicing tape layer. The semiconductor spacer structure may further comprise a release adhesive at an interface between the backgrinding tape layer and the spacer adhesive layer to facilitate removal of the backgrinding tape layer from the spacer adhesive layer.

A second aspect of the present invention is directed to a method for attaching a semiconductor spacer die to a support surface. A first subassembly, comprising a spacer wafer having first and second sides, a backgrinding tape layer and a spacer adhesive layer between the first side and the backgrinding tape layer, is obtained. The second side of the spacer wafer is background to create a second subassembly. The second subassembly is secured to a dicing tape with the backgrinding tape layer exposed. The backgrinding tape is removed from the spacer adhesive layer. An array of grooves is formed through the spacer adhesive layer and to at least the dicing tape layer to create spacer/adhesive die structures. The spacer/adhesive die structures comprise spacer die and adhesive. A spacer/adhesive die structure is secured to a support surface with the spacer adhesive layer exposed. A second spacer adhesive layer may be adhered to the second side of the spacer wafer after the backgrinding step and before the first securing step, whereby the second spacer adhesive layer can be used to secure the spacer/adhesive die structure to the support surface.

A third aspect of the invention is directed to a method for assembling a multi-chip semiconductor package. A first subassembly, comprising a semiconductor spacer wafer having first and second sides, a backgrinding tape layer and a spacer adhesive layer between the first side and the backgrinding tape layer, is obtained. The second side of the spacer wafer is background to create a second subassembly. The second subassembly is secured to a dicing tape with the backgrinding tape layer exposed. The backgrinding tape is removed from the spacer adhesive layer. An array of grooves, extending from the spacer adhesive layer to at least the dicing tape layer, is formed to create spacers/adhesive die structures. The spacer/adhesive die structures comprise spacer die and adhesive. A spacer/adhesive die structure is secured to a support surface with the spacer adhesive layer exposed. A second circuit die is positioned against the adhesive of the spacer/adhesive die structure to secure the second circuit die to the spacer die. The method may also include adhering a second spacer adhesive layer to the second side of the spacer wafer after the backgrinding step and before the first securing step, whereby the second spacer adhesive layer can be used to secure the spacer/adhesive die structure to the support surface during the second securing step. Various features and advantages of the invention will appear from the following description in which the preferred embodiments have been set forth in detail in conjunction with the accompanying drawings.

### BRIEF DESCRIPTION OF THE DRAWINGS

FIG. 1 is a side view of a spacer wafer, that is a semiconductor wafer to be diced into individual spacer die;

FIG. 2 illustrates bonding of a first side of the spacer wafer of FIG. 1 to the spacer adhesive layer of a backgrinding tape assembly;

FIG. 3 illustrates a first subassembly created from the structure of FIG. 2 and ready for backgrinding;

FIG. 4 shows backgrinding of the second side of the spacer wafer of the subassembly of FIG. 3 to create a second subassembly;

FIG. 5 illustrates the second subassembly of FIG. 4 with the background second side of the spacer wafer adhered to a dicing tape;

FIG. 6 illustrates the application of heat or UV radiation to the structure of FIG. 5;

FIG. 7 shows the backgrinding tape layer being removed from the spacer adhesive layer of FIG. 6 to create a third subassembly;

FIG. 8 shows the third subassembly of FIG. 7 after an array of grooves has been formed therein to create a plurality of spacer/adhesive die structures;

FIG. 9 illustrates an individual spacer/adhesive die structure;

FIG. 10 illustrates a multi-chip module in which the spacer/adhesive die structure of FIG. 9 has been used to mount a third circuit die to a second circuit die;

FIGS. 11-17 illustrate an alternative embodiment of the invention;

FIG. 11 illustrates a second spacer adhesive layer mounted to the second, background side of the spacer wafer of the second subassembly of FIG. 4; and

FIGS. 12-17 are similar to FIGS. 5 and 7-10 showing the creation of an adhesive/spacer/adhesive die structure in FIG. 16 to create the multi-chip module of FIG. 17.

### DETAILED DESCRIPTION

The invention will now be described in further detail by reference to the drawings, which illustrate alternative embodiments of the invention. The drawings are diagrammatic, showing features of the invention and their relation to other features and structures, and are not made to scale. For improved clarity of presentation, in the FIGs. illustrating embodiments of the invention, elements corresponding to elements shown in other drawings are not all particularly renumbered, although they are all readily identifiable in all the FIGs.

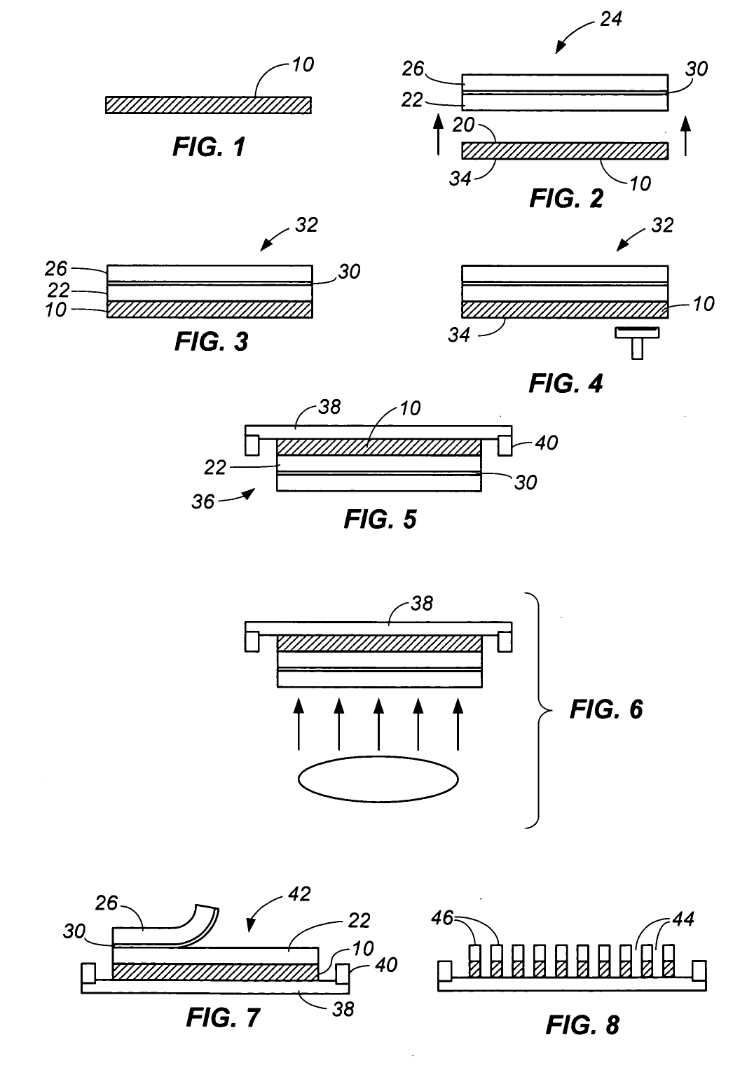

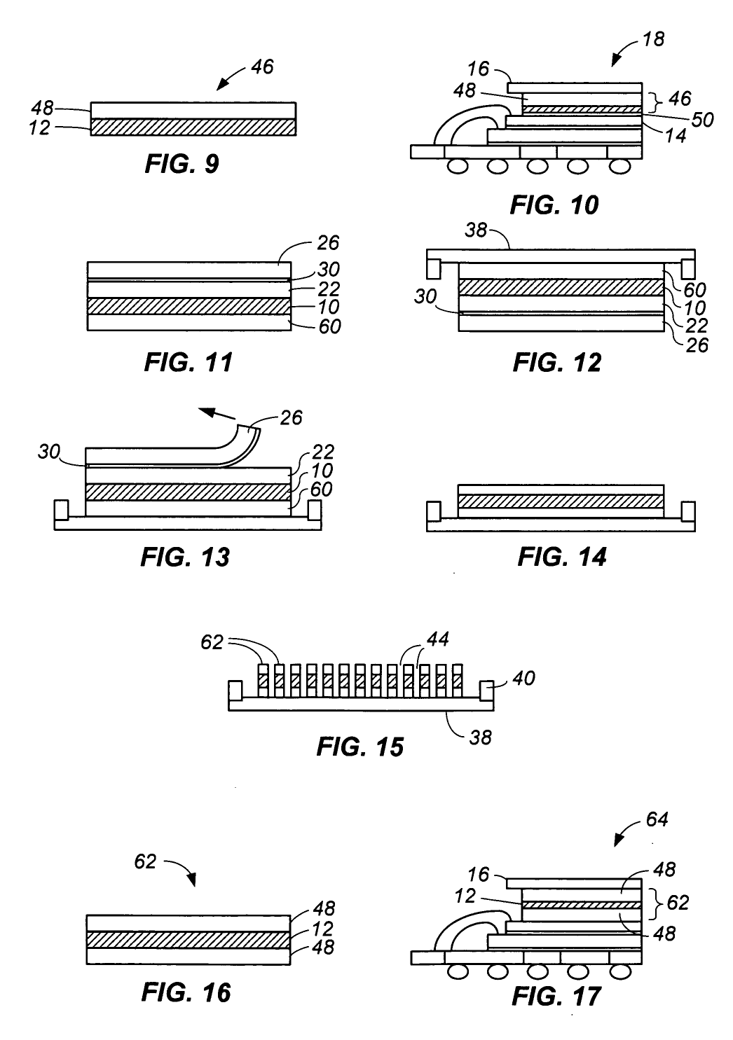

FIG. 1 is a side view of a spacer wafer 10. Spacer wafers are semiconductor wafers which will be diced into individual spacer die 12, see FIG. 9. Spacer die 12 are typically used to separate circuit die 14, 16 in a multi-chip package 18. FIG. 2 illustrates bonding of a first side 20 of spacer wafer 10 to spacer adhesive layer 22 of a backgrinding tape assembly 24. Spacer adhesive layer 22 is typically a dielectric film adhesive, such as available from Lintec Corporation as Lintec LE5000. Assembly 24 has a backgrinding tape layer 26 releasably adhered to spacer adhesive layer 22 by a release adhesive 30. As is described below, release adhesive 30 is designed to permit backgrinding tape layer 26 to separate from adhesive layer 22. However, release adhesive 30 is formulated so as not to interfere with the adhesive properties and action of layer 22 during or after subsequent processing steps.

A first subassembly 32, shown in FIG. 3, is created from the structure of FIG. 2 and is ready for backgrinding. FIG. 4 shows backgrinding of the second side 34 of spacer wafer 10 of first subassembly 32 to create a second subassembly 36. Providing both backgrinding tape layer 26, release adhesive 30 and spacer adhesive layer 22, instead of just backgrinding tape layer 26 and release adhesive 30, provides additional protection for wafer 10 during the backgrinding operation. It also facilitates assembly of multi-chip module 18 as described below.

The background second side 34 of spacer wafer 10 of second subassembly 36 of FIG. 4 is shown in FIG. 5 adhered to a dicing tape 38 within a ring frame 40. FIG. 6 illustrates the application of heat or UV radiation to help reduce the binding strength of the release adhesive 30 between backgrinding tape layer 26 and spacer adhesive layer 22 during the backgrinding tape removal step of FIG. 7. The choice of UV or heat, or the need for any type of activity to reduce the adhesive binding strength of release adhesive 30, depends, at least in part, on the composition of release adhesive 30 and of spacer adhesive layer 22, the processing environment and the type of surface being bonded. FIG. 7 shows backgrinding tape layer 26 being removed from spacer adhesive layer 22 of FIG. 6 to create a third subassembly 42. Backgrinding tape layer 26 may be removed using, for example, equipment also sold by Tokyo Seimitsu Co Ltd. (TSK) of Tokyo, Japan.

After removal of backgrinding tape layer 26, an array of grooves 44 is formed in third subassembly 42 of FIG. 7. See FIG. 8. This typically accomplished using a laser dicing saw; conventional dicing saw equipment is sold by Disco Corporation of Tokyo, Japan. This creates a plurality of spacer/adhesive die structures 46. Spacer/adhesive die structures 46 comprise spacer die 12 and adhesive 48. See FIG. 9. The edges of adhesive 48 are defined by this dicing step.

FIG. 10 illustrates multi-chip module 18 with spacer die 12 secured to the second circuit die by a bonding adhesive 50. This may be accomplished using, for example, conventional die attach equipment, such as available from Esec of Cham, Switzerland as Esec 2008. Bonding adhesive 50 may be, for example, conventional or unconventional film or paste adhesive applied to second circuit die 14. The spacer/adhesive die structure 46 of FIG. 9 has been used to mount third circuit die 16 spacer die 12 at a position spaced-apart above a second circuit die 14 without the need for any additional adhesive application steps, such as is needed if an adhesive paste or an adhesive film is applied between a spacer die and third circuit die 16. Any residual release adhesive 30 does not materially affect the bond between spacer die 12 and circuit die 16 created by adhesive 48.

FIGS. 11-17 illustrate an alternative embodiment of the invention with like reference numbers referring to like elements. A second spacer adhesive layer 60 is shown in FIG. 11 adhered to the second, background side 34 of spacer wafer 10 of second subassembly 36 of FIG. 4. FIGS. 12-17 are similar to FIGS. 5 and 7-10 and show the creation of an adhesive/spacer/adhesive die structure 62 in FIG. 16 to create multi-chip module 64 of FIG. 17. If desired or necessary, a process to reduce the binding strength of release adhesive 30, as shown in FIG. 6, may also be used. The existence of adhesive 48 on both sides of spacer die 12 of FIG. 16 eliminates the need to provide bonding adhesive 50 between, for example, second circuit die 14 and spacer die 12.

As mentioned above, the present invention helps to protect wafer 10 during backgrinding operations and facilitates assembly of multi-chip packages. The present invention can also improve die stack quality for die chip, crack and film burr, and die stack design clearance without resin bleed.

Other modification and variation can be made to the disclosed embodiments without departing from the subject of the invention as defined in following claims. For example, spacer/adhesive die structure 46 and adhesive/spacer/adhesive die structure 62 may be used to support other spacer die as well as circuit die.

Any and all patents, patent applications and printed publications referred to above are incorporated by reference.

Other embodiments are within the scope of the invention.

1. A semiconductor spacer structure comprising:
a backgrinding tape layer, followed by
a spacer adhesive layer, followed by
a semiconductor spacer layer, followed by
a dicing tape layer.

2. The semiconductor spacer structure according to claim 1 further comprising a second spacer adhesive layer between the semiconductor spacer layer and the dicing tape layer.

3. The semiconductor spacer structure according to claim 1 wherein the spacer adhesive layer comprises a dielectric spacer adhesive layer.

4. The semiconductor spacer structure according to claim 1 wherein the spacer adhesive layer comprises an epoxy adhesive.

5. The semiconductor spacer structure according to claim 1 wherein the semiconductor spacer layer comprises a semiconductor wafer.

6. The semiconductor spacer structure according to claim 1 further comprising a release adhesive at an interface between the backgrinding tape layer and the spacer adhesive layer to facilitate removal of the backgrinding tape layer from the spacer adhesive layer.

7. A semiconductor spacer structure comprising:
a backgrinding tape layer, followed by
a spacer adhesive layer, followed by
a semiconductor spacer wafer, followed by
a second spacer adhesive layer, followed by
a dicing tape layer, and
a release adhesive at an interface between the backgrinding tape layer and the spacer adhesive layer to facilitate removal of the backgrinding tape layer from the spacer adhesive layer.

8. A method for attaching a semiconductor spacer die to a support surface comprising:
obtaining a first subassembly comprising a spacer wafer having first and second sides, a backgrinding tape layer and a spacer adhesive layer between the first side and the backgrinding tape layer;
backgrinding the second side of the spacer wafer to create a second subassembly;
securing the second subassembly to a dicing tape with the backgrinding tape layer exposed;
removing the backgrinding tape from the spacer adhesive layer;
forming an array of grooves extending from the spacer adhesive layer to at least the dicing tape layer and thereby creating spacers/adhesive die structures, the spacer/adhesive die structures comprising spacer die and adhesive; and
securing a spacer/adhesive die structure to a support surface with the spacer adhesive layer exposed.

9. The method according to claim 8 wherein the removing step is carried out after the first securing step.

10. The method according to claim 8 further comprising adhering a second spacer adhesive layer to the second side of the spacer wafer after the backgrinding step and before the first securing step, whereby the second spacer adhesive layer can be used to secure the spacer/adhesive die structure to the support surface.

11. The method according to claim 8 wherein the obtaining step is carried out so that the first subassembly comprises a release adhesive at an interface between the backgrinding tape layer and the spacer adhesive layer to facilitate the backgrinding tape removing step.

12. A method for assembling a multi-chip semiconductor package comprising:
obtaining a first subassembly comprising a semiconductor spacer wafer having first and second sides, a backgrinding tape layer and a spacer adhesive layer between the first side and the backgrinding tape layer;
backgrinding the second side of the spacer wafer to create a second subassembly;
securing the second subassembly to a dicing tape with the backgrinding tape layer exposed;
removing the backgrinding tape from the spacer adhesive layer;
forming an array of grooves extending from the spacer adhesive layer to at least the dicing tape layer and thereby creating spacers/adhesive die structures, the spacer/adhesive die structures comprising spacer die and adhesive;
securing a spacer/adhesive die structure to a support surface with the spacer adhesive layer exposed; and
positioning a second, circuit die against the adhesive of the spacer/adhesive die structure to secure the second, circuit die to the spacer die.

13. The method according to claim 12 further comprising adhering a second spacer adhesive layer to the second side of the spacer wafer after the backgrinding step and before the first securing step, whereby the second spacer adhesive layer is used to secure the spacer/adhesive die structure to the support surface during the second securing step.
